(19) United States
(12) Patent Application Publication
(10) Pub. No.: US 2013/0164948 A1
(43) Pub. Date: Jun. 27, 2013

(54) METHODS FOR IMPROVING WAFER TEMPERATURE UNIFORMITY

(71) Applicants: Martin Romero, San Jose, CA (US); Jason Wright, Saratoga, CA (US)

(72) Inventors: Martin Romero, San Jose, CA (US); Jason Wright, Saratoga, CA (US)

(73) Assignee: Intermolecular, Inc., San Jose, CA (US)

(21) Appl. No.: 13/335,261

(22) Filed: Dec. 22, 2011

(51) Int. Cl. H01L 21/26

(52) U.S. Cl. 438/795; 257/E21.328

(57) ABSTRACT

A method of improving temperature uniformity across a wafer or substrate is provided. The inventors have discovered that thermal radiation reflected from the showerhead injector affects the temperature uniformity across the wafer. Temperature uniformity across the wafer, particularly from the center to edge of the wafer, is improved by controlling the reflected energy from the showerhead. Control of the reflected energy from the showerhead is achieved by a variety of means, including changing the emissivity of the showerhead, creating different zones of emissivity of the showerhead, selectively heating the showerhead, varying the distance between the showerhead and the wafer, and increasing reflectivity of the showerhead in selected regions by employing an ring configured to emit thermal radiation to the showerhead which is then reflected back to the wafer.

### TECHNICAL FIELD

The present disclosure relates generally to the field of semiconductor processing, and more particularly to methods and systems for improving temperature uniformity across a wafer or substrate during processing.

### BACKGROUND

Thermal processing of wafers is commonly used in the manufacture of semiconductors. Chemical deposition processes are commonly used in the semiconductor industry to deposit a layer or film over a wafer or substrate. Chemical vapor deposition (CVD) is one such commonly used process. As device densities have continued to shrink, atomic layer deposition (ALD) has become an alternative process to CVD for the deposition of thin films.

Traditional semiconductor processes and systems have been confined to processing of the full substrate, or “blanket” processing. In some instances it may be desirable to process selected regions of the substrate independently, or in a different manner. For example, it may be very valuable to independently process selected regions of the substrate in order to evaluate different materials, different unit process conditions or parameters, different sequencing and integration of processes, and combinations thereof. This capability, hereinafter referred to as “combinatorial processing,” is generally not available with systems that are designed specifically for conventional full substrate processing. Moreover, it may be desirable to subject selected regions of the substrate to different processing conditions (referred to as “site-isolated deposition”) in one step, and then subject the full substrate to a similar processing condition, or a different condition, in another step.

Critical during the processing of semiconductors is uniform heating of the substrate or wafer. Non-uniform heating of the substrate, particularly non-uniform lateral heating from the center to the edge of the substrate, is a significant problem during processing. Temperature variations can cause non-uniformities in the films and materials deposited on the substrate, distorted dopant patterns, and can impart substantial stresses on the substrate, among other undesirable effects. While much effort has been focused on uniform heating of substrates, problems and challenges remain. Accordingly, further advances and developments are needed.

### SUMMARY

A method of improving temperature uniformity across a wafer or substrate is provided. The inventors have observed that thermal radiation emitted and reflected from the injector assembly affects the temperature uniformity across the wafer. The inventors discovered that temperature uniformity across the wafer, particularly from the center to edge of the wafer, can be modulated by controlling the reflected energy from the injector assembly. Reflectivity of an object or material can be broadly defined as the amount or fraction of incident radiation reflected by its surface. Emissivity of an object or material (c) is the relative ability of its surface to emit energy by radiation, and is defined as the ratio of energy radiated by a particular material to energy radiated by a black body at the same temperature. For an opaque object, emissivity is the reciprocal of reflectivity. Control of the reflected energy from the injector assembly, such as a showerhead injector, is achieved by a variety of means, including changing the emissivity of the showerhead, creating different zones of emissivity of the showerhead, selectively heating the showerhead, varying the distance between the showerhead and the wafer, and increasing thermal energy radiating from the showerhead in selected regions by employing an ring configured to emit thermal radiation to the showerhead which is then reflected back to the wafer.

In some embodiments, a method of improving temperature uniformity across a substrate during processing in a chamber having an injector assembly is provided, comprising the steps of: heating the substrate; and modulating thermal energy reflected from the injector assembly to at least a portion of the substrate.

In some embodiments, a method of improving temperature uniformity across a substrate or wafer during processing in a chamber is provided. The chamber includes a heater configured to heat the substrate and an injector configured to inject fluids to process the substrate. Reflectivity of the injector is controlled to reflect variable thermal energy to the substrate. In some embodiments, the thermal energy flux from the injector is varied by changing the emissivity of the injector. Optionally, the injector may comprise different zones of emissivity such that selective regions of the injector radiate different amounts of energy back to the substrate. In other embodiments, the injector is selectively heated. In further embodiments, the distance between the injector and the substrate may be varied.

In some embodiments, the reflectivity of the injector is increased in selected regions by employing an ring configured to emit thermal radiation to the injector which is then reflected back to the substrate.

In some embodiments, a method of combinatorially processing a substrate in a chamber having an injector assembly is provided, comprising the steps of: heating the substrate; and modulating thermal energy reflected from the injector assembly to site-isolated regions on the substrate. The injector assembly may include a bottom surface positioned adjacent the substrate, wherein the bottom surface of the injector assembly exhibits multiple zones of emissivity. In some embodiments, the one or more of the multiple zones exhibits different emissivity value. In some embodiments, the one or more multiple zones of emissivity correspond to one or more site-isolated regions on the substrate

Other aspects of the present disclosure will become apparent from the following detailed description, taken in conjunction with the accompanying drawings. Several inventive embodiments are described below.

### BRIEF DESCRIPTION OF THE DRAWINGS

Embodiments of the present disclosure will be readily understood by the following detailed description in conjunction with the accompanying drawings, where like reference numerals designate like structural elements.

FIG. 1 illustrates a schematic diagram for implementing combinatorial processing and evaluation using primary, secondary, and tertiary screening;

FIG. 2 is a schematic diagram illustrating a general methodology for combinatorial process sequence integration that includes site isolated processing and/or conventional processing in accordance with one embodiment of the present disclosure;

FIG. 3 is a simplified cross-sectional schematic of a processing chamber in accordance with some embodiments of the present disclosure;

FIG. 4 is a partial, cross-sectional view of a processing chamber in accordance with some embodiments of the present disclosure; and

FIG. 5 is an exploded, perspective view showing a substrate with deposition ring and showerhead injector assembly in accordance with some embodiments of the present disclosure.

### DETAILED DESCRIPTION

Embodiments of the present disclosure provide apparatus and methods for improving temperature uniformity across a wafer or substrate. The inventors have discovered that thermal radiation reflected from the injector assembly, such as but not limited to a showerhead injector, affects the temperature uniformity across the wafer. Temperature uniformity across the wafer, particularly from the center to edge of the wafer, is improved by controlling the reflected energy from the injector.

As described in detail below, control of the reflected energy from the injector assembly is achieved in a variety of ways, including changing the emissivity of the injector assembly, creating different zones of emissivity of the injector assembly, selectively heating the injector assembly, varying the distance between the injector assembly and the wafer, and increasing reflectivity of the injector assembly in selected regions by employing an ring configured to emit thermal radiation to the injector assembly which is then reflected back to the wafer.

Methods of the present disclosure described herein may be used in a variety of semiconductor processes where an injector assembly, such as a showerhead injector, is used to deliver processing fluids to a wafer or substrate that is heated. In addition to depositing a layer of material over an entire substrate, the embodiments described below provide details for a multi-region processing system that enable processing a substrate in a combinatorial fashion. Thus, different regions of the substrate may have different properties, which may be due to variations of the materials, unit process conditions or parameters, and process sequences, etc. Within each region the conditions are preferably substantially uniform so as to mimic conventional full wafer processing, however, valid results can be obtained for certain experiments without this requirement. In some embodiments, the different regions are isolated so that there is no interaction between the different regions.

It should be appreciated that the combinatorial processing of the substrate may be combined with conventional processing techniques where substantially the entire substrate is uniformly processed, e.g., subjected to the same materials, unit processes and process sequences. The embodiments described herein can perform combinatorial deposition processing and conventional full substrate processing in the same chamber. Consequently, in one substrate processed in the same chamber, information concerning the varied processes and the interaction of the varied processes with the conventional processes can be evaluated. Accordingly, a multitude of data is available from a single substrate for a desired process.

The manufacture of semiconductor devices entails the integration and sequencing of many unit processing steps. As an example, semiconductor manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference in their entirety. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference in their entirety.

HPC processing techniques have been successfully adapted to wet chemical processing such as etching, texturing, polishing, cleaning, etc. HPC processing techniques have also been successfully adapted to deposition processes such as s chemical vapor deposition (CVD), as well as atomic layer deposition (ALD) as described herein.

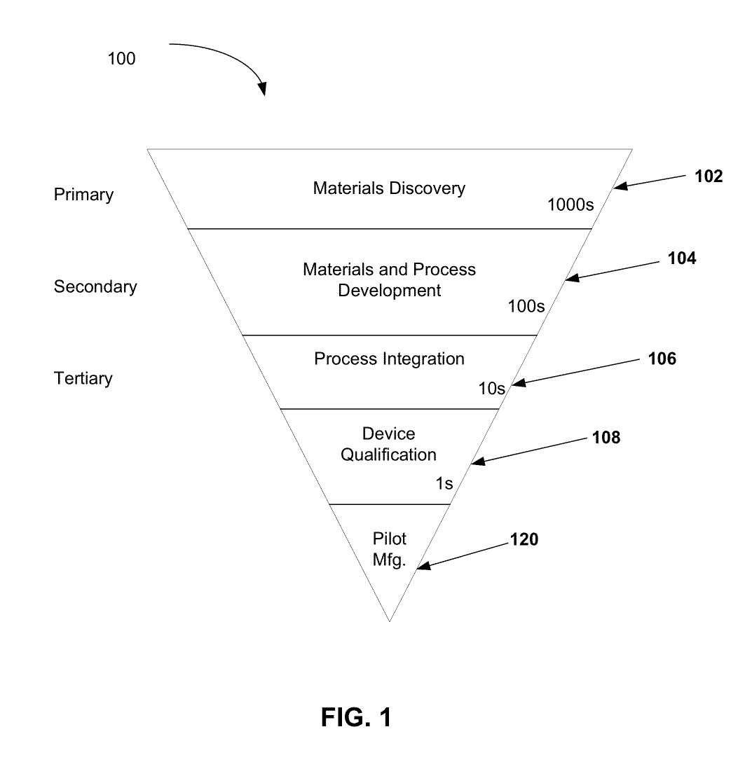

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007 which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of semiconductor manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a semiconductor device. A global optimum sequence order is therefore derived and as part of this derivation, the unit processes, unit process parameters and materials used in the unit process operations of the optimum sequence order are also considered.

The embodiments described further analyze a portion or sub-set of the overall process sequence used to manufacture a semiconductor device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate that are equivalent to the structures formed during actual production of the semiconductor device. For example, such structures may include, but would not be limited to, contact layers, buffer layers, absorber layers, or any other series of layers or unit processes that create an intermediate structure found on semiconductor devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

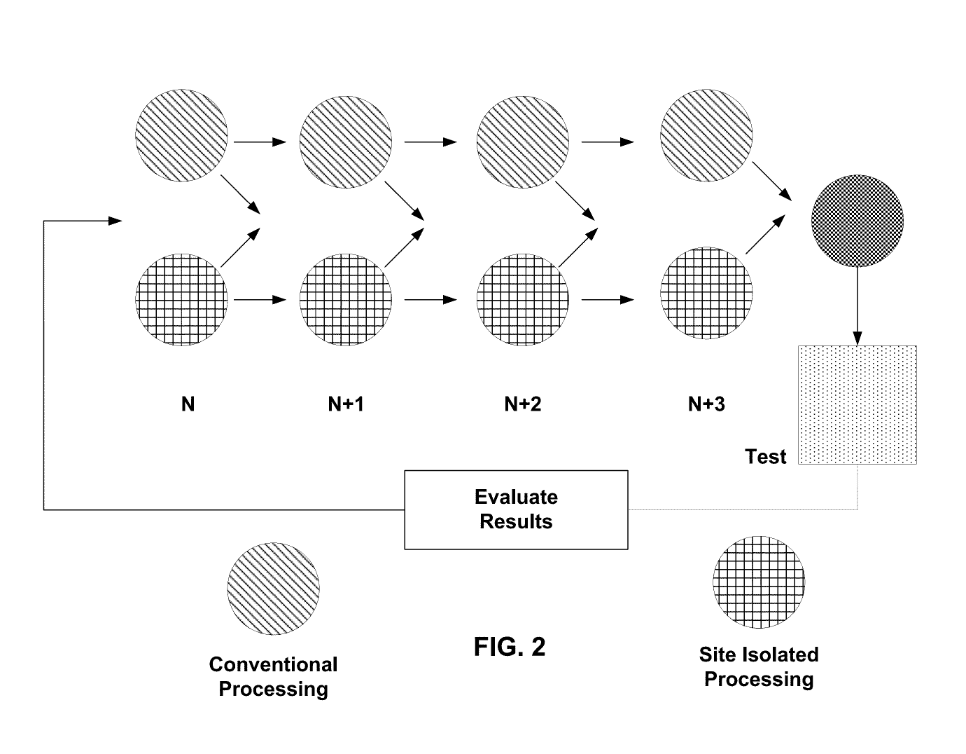

FIG. 2 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in semiconductor manufacturing may be varied.

As mentioned above, within a region, the process conditions are substantially uniform, in contrast to gradient processing techniques which rely on the inherent non-uniformity of the material deposition. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

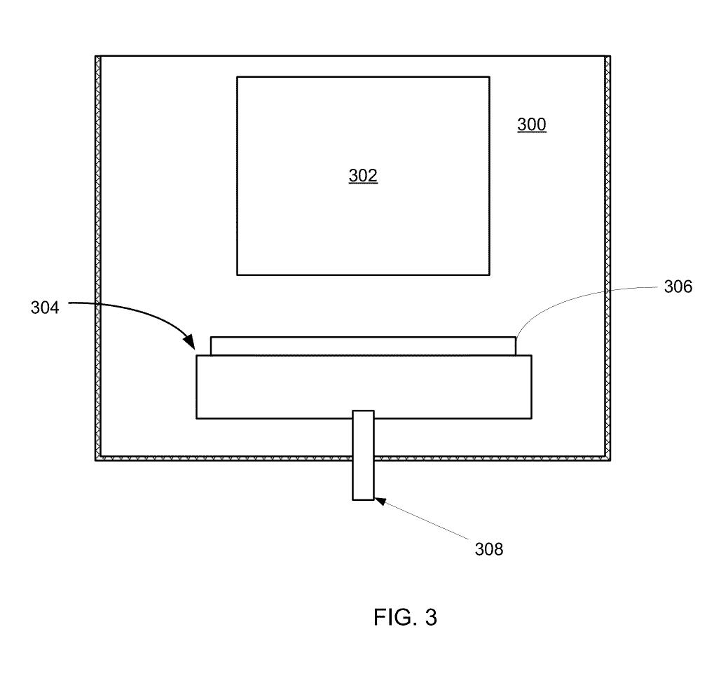

FIG. 3 is a simplified cross-sectional schematic diagram of one example of a process chamber 300 according to embodiments of the present disclosure. The process chamber 300 may be any type of chamber used in semiconductor processing, such as for example without limitation, a chemical vapor deposition (CVD) chamber, atomic layer deposition (ALD) chamber, plasma enhanced or assisted CVD or ALD chambers, combinatorial processing chambers, and the like.

The process chamber 300 generally includes an injector assembly 302 for delivering processing fluids, such as chemical precursors or reactants, for carrying out the various processes, and a substrate support 304 that supports one or more substrates 306 or wafers to be processed. The substrate support 304 may be configured for independent and/or combinatorial heating of different regions of the substrate. The substrate support 304 may be any suitable support. For example the substrate support may be comprised of a susceptor that is heated by induction coils (not shown). The susceptor may be fixed or rotating. Generally, the substrate support 304 is coupled to a lift system 308 so that the substrate support 304 may be moved vertically within the chamber to vary the relative distance (d) of the substrate 306 to the injector assembly 302.

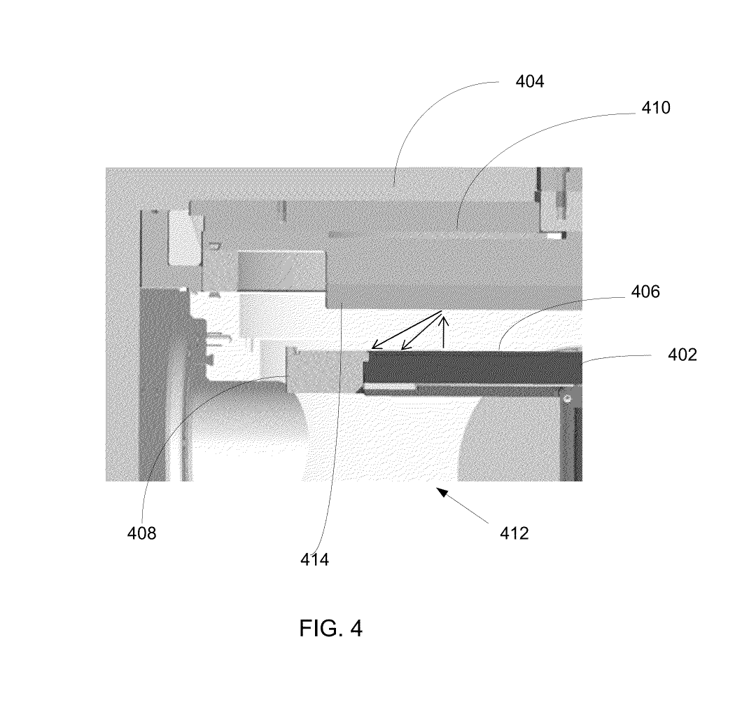

FIG. 4 is a partial cross-sectional view of a chamber 400 showing another example of a substrate support 402 and injector assembly 404. In this embodiment, substrate support 402 includes an ring 408 which encircles the periphery of a substrate 406. The substrate support 402 is typically heated. Any suitable heating mechanism may be used, for example and without limitation, induction coils (not shown) may be embedded in or coupled to the substrate support 402.

In the exemplary embodiment the injector assembly 404 is comprised of a showerhead injector and is positioned above the substrate 406. The substrate support 402 includes a lift 412 configured to raise and lower the substrate support 402 in order to vary the relative distance (d) of the substrate 406 to a bottom surface 414 of the injector assembly 404. The injector assembly 404 may be heated, for example by induction coils 410 embedded in the injector assembly.

As discussed above, uniform heating across the entire surface of the substrate 406 is difficult to achieve, particularly from the center to the of the substrate 406. Substantial computer simulation and experimentation determined that the reflection of thermal radiation from the injector assembly 404 affects the temperature uniformity across the substrate 406. This discovery was not expected. Prior art techniques have all focused on control of the active heating elements, such as the induction coils in the substrate support, and the like. The effect of energy reflected from the injector assembly was not understood to contribute to non-uniform heating of the substrate.

Temperature uniformity across the wafer, particularly from the center to edge of the wafer, is improved by controlling the reflected energy from the injector assembly. Referring again to FIG. 4, arrows are used to illustrate energy radiating from the substrate support, hitting the injector assembly and then radiating back towards the wafer. Reflectivity, or the amount of energy reflected from the injector assembly, may be controlled in a variety of ways. Additionally, and of significant advantage, the teaching of the invention provides for selective control of reflectivity of the injector assembly in order to offset or modulate temperature non-uniformities across the substrate. In other words, the reflectivity of (or the thermal energy radiated from) the injector assembly may be made to vary in select locations in order to compensate for temperature non-uniformities. For example, if the substrate tends to be at a higher temperature in its center, relative to its edge, the reflectivity of the injector assembly may be greater at the edges and less in the center such that more energy is reflected to the edge of the substrate and less energy is reflected to the center of the substrate from the injector assembly.

To control the emitted and reflected thermal energy from the injector assembly a number of embodiments are provided. For example, and without limitation, varying the thermal energy radiating from the injector assembly may be achieved by any one or more of: changing the emissivity (c) of the injector assembly, creating different zones of emissivity of the injector assembly, selectively heating the showerhead, varying the distance between the showerhead and the wafer, and increasing reflectivity of the showerhead in selected regions by employing an ring configured to emit thermal radiation to the showerhead which is then reflected back to the wafer, and combinations thereof.

Emissivity of an object or material (ε) is the relative ability of its surface to emit energy by radiation, and is defined as the ratio of energy radiated by a particular material to energy radiated by a black body at the same temperature. Reflectivity of an object or material can be broadly defined as the amount or fraction of incident radiation reflected by its surface. For an opaque object, emissivity is the reciprocal of reflectivity. In some embodiments, the emissivity of the bottom surface 414 of the injector assembly 402 is selected such that more, or less, energy is reflected from the injector assembly 402 to the substrate 406. In some embodiments, the bottom surface 414 of the injector assembly 402 comprises different zones of emissivity selected to compensate for temperature non-uniformities across the substrate 406.

In some embodiments, the emissivity of the injector assembly 402 may vary in the range of about 0.05 to about 0.9, and in some embodiments the emissivity of the injector assembly may vary in the range of about 0.1 to about 0.4. In other embodiments, different zones of emissivity may be provided. In one example the bottom surface 414 of the injector assembly 402 may include an inner and an outer zone, and where the inner zone has a high emissivity relative to the outer zone which has a low emissivity. In one example, the inner zone has an emissivity in the range of about 0.2 to about 0.4, and the outer zone has an emissivity in the range of about 0.05 to about 0.2 Alternatively, the bottom surface 414 of the injector may be divided into separate sections (such as but not limited to four quadrants) where one or more of the sections exhibit different emissivity. It should be appreciated that any number of separate sections or zones of emissivity may be used, and that the sections or zones can have any suitable shape.

The emissivity of the injector assembly may be varied in a number of ways. For example, materials with different emissivity values may be used. Examples of materials with different emissivity values include but are not limited to: alumina, aluminum nitride, silicon carbide, and metals such as nickel, stainless steel and aluminum.

In other embodiments, the emissivity of the bottom surface 414 may be modified by surface treatment. Any suitable surface treatment may be used. For example, in some embodiments all or a portion of the bottom surface 414 may be plated, such as with a nickel plating to provide a high emissivity surface. Alternatively, all or a portion of the bottom surface 414 may be roughened or anodized to provide a low emissivity surface. In one example, the center of the bottom surface 414 is black anodize, and the peripheral edge of the bottom surface 414 is plated with nickel.

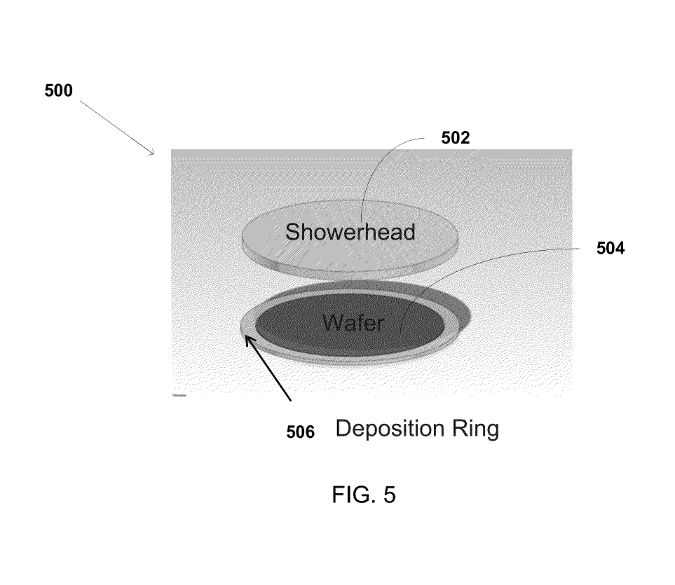

In some embodiments, an ring may be employed to adjust the reflectivity of energy to the substrate as shown in FIG. 5. The ring 506 encircles the substrate 504 and may be configured to increase thermal energy transmitted to the injector and reflected to the peripheral edge of the substrate 504. In some embodiments, the ring 506 is substantially flush with the top surface of the substrate 504 and there may be a small gap between the edge of the substrate and the ring.

To increase thermal radiation to the edge of the substrate 504, the ring 506 may be made of a material with relatively high emissivity, such as in the range of about 0.6 to about 0.9, and the like. The ring 506 may be coated with nickel plate, or other suitable surface treatment, to decrease its emissivity. Further, the ring 506 may be independently heated to increase its thermal energy emitted. In some embodiments, the ring 506 is heated in the range of about 250 to about 550° C., and in other embodiments the ring 506 is heated in the range of about 550° C. to about 750° C.

Further control of the temperature uniformity across the substrate may be achieved by varying the distance of the substrate to the injector assembly. Referring again to FIG. 4, the substrate support 402 is carried by a lift 412 which is configured to move the substrate support 402 vertically within the process chamber 400. Reflectivity of energy from the injector assembly 404 may be increased to the substrate 406 by moving the substrate closer to the bottom surface 414 of the injector assembly 404. In some embodiments, the distance (d) from the bottom surface 414 of the injector assembly 404 to the substrate 406 is in the range of about 0.2 inches to about 5 inches, and in other embodiments in the range of about 0.35 inches to about 3 inches.

According to the present disclosure, one, more, or all of these techniques may be employed as desired to improve the temperature uniformity across the substrate. Of particular advantage, the present disclosure provides significant flexibility and selective control of the temperature environment impacting the substrate.

### Simulation

A number of simulations were performed using finite element software and are described herein for illustration purposes only and without limiting the scope of the inventive embodiments in any way.

The temperature range across a wafer was simulated in a number of different system configurations and under various process conditions. The temperature range across the wafer is measured from the center to the edge of the wafer.

Showerhead injectors of different emissivity were simulated. Specifically, showerhead injectors having emissivity values of 0.1, 0.2 and 0.4 were simulated. The distance between the wafer and bottom surface of the showerhead was also varied to determine the effect on temperature uniformity across the wafer. Additionally, a heated ring was used in some of the simulations to determine its effect on the temperature uniformity.

A summary of the simulations performed at the various process conditions is shown in Table 1 below. As illustrated, the temperature range across the wafer can be substantially improved.

TABLE 1

| | Temp | Wafer-SH | | Temperature | Temperature |
|---|---|---|---|---|---|
| | Dep Ring | Gap | Emissivity | Max | Range |
| Case | (° C.) | (inch) | SH | (° C.) | (° C.) |
| 1 | N/A | 0.35 | 0.1 | 504 | 16.8 |
| 2 | N/A | 0.35 | 0.2 | 485 | 11.5 |
| 3 | N/A | 0.35 | 0.4 | 460 | 5.7 |
| 4 | 550 | 0.35 | 0.2 | 488 | 4.1 |
| 5 | 100 | 0.35 | 0.2 | 485 | 10.3 |
| 6 | N/A | 5.0 | 0.2 | 433 | 1.9 |
| 7 | 550 | 5.0 | 0.2 | 435 | 1.7 |

The inventive embodiments described herein may be used in any type of chamber or combination of chambers and the description herein is merely illustrative of one possible combination and not meant to limit the potential chamber or processes that can be supported to combine combinatorial processing or combinatorial plus conventional processing of a substrate or wafer. A plurality of methods, such as but not limited to combinatorial CVD and ALD processes, may be employed to deposit material upon the substrate employing combinatorial processes.

The invention has been described in relation to particular examples, which are intended in all respects to be illustrative rather than restrictive. Various aspects and/or components of the described embodiments may be used singly or in any combination. It is intended that the specification and examples be considered as exemplary only, with a true scope and spirit of the invention being indicated by the claims.

What is claimed is:

1. A method of improving temperature uniformity across a substrate during processing in a chamber having an injector assembly, comprising the steps of:
heating the substrate; and
modulating thermal energy reflected from the injector assembly to at least a portion of the substrate.

2. The method of claim 1 wherein the injector assembly comprises a bottom surface positioned adjacent the substrate, and the step of modulating the thermal energy comprises varying emissivity of the bottom surface of the injector assembly.

3. The method of claim 2 wherein the bottom surface of the injector assembly has a diameter which exceeds the diameter of the substrate by up to 25%.

4. The method of claim 2 wherein the bottom surface exhibits emissivity values in the range of about 0.05 to about 0.9.

5. The method of claim 2 wherein the bottom surface exhibits emissivity values in the range of about 0.1 to about 0.4.

6. The method of claim 2 wherein the bottom surface is comprised of multiple zones of emissivity, and where one or more of the multiple zones exhibits different emissivity values.

7. The method of claim 1 wherein the step of modulating the thermal energy further comprises varying a distance between the substrate and the injector assembly.

8. The method of claim 7 wherein the distance is varied in a range of about 0.2 to about 5.0 inches.

9. The method of claim 1 further comprising selectively heating different regions of the injector assembly.

10. The method of claim 1 wherein the step of modulating thermal energy reflected from the injector assembly further comprises placing a ring around the periphery of the substrate.

11. The method of claim 10 wherein the ring exhibits emissivity values in the range of about 0.05 to about 0.9.

12. The method of claim 10 further comprising heating the ring to a temperature in the range of about 250° C. to about 750° C.

13. The method of claim 2 wherein the bottom surface of the injector assembly is comprised of any one or more of: alumina, aluminum, aluminum nitride, silicon carbide, nickel, or stainless steel.

14. A method of combinatorially processing a substrate in a chamber having an injector assembly, comprising the steps of:
heating the substrate; and
modulating thermal energy reflected from the injector assembly to site-isolated regions on the substrate.

15. The method of claim 14 further comprising varying a distance between the substrate and the injector assembly.

16. The method of claim 14 wherein the injector assembly comprises a bottom surface positioned adjacent the substrate, wherein the bottom surface of the injector assembly exhibits multiple zones of emissivity, and where one or more of the multiple zones exhibits a different emissivity value.

17. The method of claim 16 wherein the one or more multiple zones of emissivity correspond to one or more site-isolated regions on the substrate.

18. The method of claim 16 wherein the bottom surface of the injector assembly exhibits emissivity values in the range of about 0.05 to about 0.9.

19. The method of claim 14 further comprising placing a ring around the periphery of the substrate.

20. The method of claim 19 further comprising heating the ring to a temperature in the range of about 250° C. to about 750° C.
